(19) United States
(12) Patent Application Publication
(10) Pub. No.: US 2024/0136175 A1
(43) Pub. Date: Apr. 25, 2024

(54) AUXILIARY PRECURSOR, THIN-FILM PRECURSOR COMPOSITION, METHOD OF FORMING THIN FILM, AND SEMICONDUCTOR SUBSTRATE FABRICATED USING METHOD

(71) Applicant: SOULBRAIN CO., LTD., Gyeonggi-do (FR)

(72) Inventors: Jae Sun JUNG, Gyeonggi-do (KR); Chang Bong YEON, Gyeonggi-do (KR); Seung Hyun LEE, Gyeonggi-do (KR); Ji Hyun NAM, Gyeonggi-do (KR); Sung Woo CHO, Gyeonggi-do (KR)

(21) Appl. No.: 18/277,074

(22) PCT Filed: Feb. 22, 2022
(86) PCT No.: PCT/KR2022/002564

§ 371 Date: Sep. 21, 2023

(30) Foreign Application Priority Data
Feb. 22, 2021 (KR) 10-2021-0023530
Feb. 22, 2022 (KR) 10-2022-0022728

(51) Int. Cl. H01L 21/02; H01L 21/3205

(52) U.S. Cl. CPC H01L 21/02214; H01L 21/02219; H01L 21/02274; H01L 21/0228; H01L 21/32051

(57) ABSTRACT

The present invention relates to an auxiliary precursor, a thin film precursor composition, a method of forming a thin film using the thin film precursor composition, and a semiconductor substrate fabricated using the method. The present invention provides the thin film precursor composition including a thin film precursor compound and a compound having a predetermined structure that exhibits reaction stability as the auxiliary precursor. By using the thin film precursor composition in a thin film deposition process, side reactions may be suppressed, and thin film growth rate may be appropriately controlled. In addition, since process by-products are removed from a thin film, even when a thin film is formed on a substrate having a complicated structure, step coverage and the thickness uniformity and resistivity characteristics of the thin film may be greatly improved. In addition, corrosion or deterioration may be prevented, and the crystallinity of the thin film may be improved, thereby improving the electrical properties of the thin film.

### TECHNICAL FIELD

The present invention relates to an auxiliary precursor, a thin film precursor composition including the auxiliary precursor, a method of forming a thin film using the thin film precursor composition, and a semiconductor substrate fabricated using the method. More particularly, the present invention relates to an auxiliary precursor that is capable of inhibiting side reactions to reduce the concentration of impurities in a thin film, is capable of preventing corrosion or deterioration of a thin film to improve the electrical properties of the thin film, is capable of appropriately controlling the growth rate of a thin film to improve step coverage and the thickness uniformity and resistivity of the thin film even when the thin film is formed on a substrate having a complicated structure, and does not decompose even when mixed with a thin film precursor; a thin film precursor composition including the auxiliary precursor; a method of forming a thin film using the thin film precursor composition; and a semiconductor substrate fabricated using the method.

### BACKGROUND ART

Development of high-integration memory and non-memory semiconductor devices is actively progressing. As the structures of memory and non-memory semiconductor devices become increasingly complex, the importance of thin film quality and step coverage is gradually increasing when depositing various thin films on substrates.

A thin film for semiconductors is made of a metal nitride, silicon nitride, a metal oxide, a metal silicide, or the like. Examples of the metal nitride include titanium nitride (TiN), tantalum nitride (TaN), zirconium nitride (ZrN), AlN, TiSiN, TiAlN, TiBN, TiON, TiCN, and the like. The thin film is generally used as a diffusion barrier between the silicon layer of a doped semiconductor and aluminum (Al) or copper (Cu) used as an interlayer wiring material. However, when depositing a tungsten (W) or molybdenum (Mo) metal thin film on a substrate, the thin film serves as an adhesion layer.

To impart excellent and uniform physical properties to a thin film deposited on a substrate, the formed thin film must have high step coverage. Accordingly, the atomic layer deposition (ALD) process using a surface reaction is used rather than the chemical vapor deposition (CVD) process using a gas phase reaction, but there are still problems to be solved to realize 100% step coverage.

In addition, to improve step coverage, a method of reducing the growth rate of a thin film has been proposed. However, when decreasing deposition temperature to reduce the growth rate of a thin film, impurities such as carbon and chlorine remaining in the thin film increase, and film quality deteriorates.

In addition, in the case of titanium tetrachloride (TiCl₄) used to deposit titanium nitride (TiN), which is a typical metal nitride, process by-products such as chlorides remain in a formed thin film, causing corrosion of metals such as aluminum. In addition, film quality deteriorates due to generation of non-volatile by-products.

Therefore, it is necessary to develop a method of forming a thin film having a complex structure that contains a small amount of residual impurities and does not cause corrosion of interlayer wiring materials and a semiconductor substrate fabricated using the method. In addition, it is necessary to develop an auxiliary precursor that is capable of providing uniform thickness and step coverage even at a high aspect ratio according to the number of VNAND stacks, which increase to 128 layers, 256 layers, 512 layers, or the like, and does not decompose even when mixed with a thin film precursor.

### RELATED ART DOCUMENTS

### Patent Documents

KR 2006-0037241 A

### DISCLOSURE

### Technical Problem

Therefore, the present invention has been made in view of the above problems, and it is one object of the present invention to provide an auxiliary precursor that is capable of greatly improving the quality of a thin film including the auxiliary precursor by providing a low bandgap, is capable of appropriately controlling the growth rate of a thin film by inhibiting side reactions, is capable of preventing corrosion or deterioration by removing process by-products from a thin film, is capable of greatly improving step coverage and the thickness uniformity and resistivity characteristics of a thin film even when the thin film is formed on a substrate having a complicated structure, and does not decompose even when mixed with a thin film precursor; a method of forming a thin film using the auxiliary precursor; and a semiconductor substrate fabricated using the method.

It is another object of the present invention to improve the density and electrical properties (e.g., resistivity) of a thin film by improving the crystallinity of the thin film.

The above and other objects can be accomplished by the present invention described below.

### Technical Solution

In accordance with one aspect of the present invention, provided is an auxiliary precursor, wherein the auxiliary precursor is a straight-chain, branched, cyclic, or aromatic compound represented by Chemical Formula 1 below, and is mixed with a thin film precursor compound and used.

AnBmXoYiZj, [Chemical Formula 1]

wherein A is carbon or silicon; B is hydrogen, an alkyl having 1 to 10 carbon atoms, a cycloalkyl having 3 to carbon atoms, or an alkoxy having 1 to 10 carbon atoms; X includes one or more of fluorine (F), chlorine (Cl), bromine (Br), and iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

When the auxiliary precursor and the thin film precursor compound are mixed at a molar ratio of 1:1, pressurized, and then an ¹H-NMR spectrum thereof is measured, the auxiliary precursor may be a compound in which an integrated value of newly generated peaks is less than 0.1% based on an ¹H-NMR spectrum for the auxiliary precursor.

In accordance with another aspect of the present invention, provided is a thin film precursor composition including an auxiliary precursor and a thin film precursor compound, wherein the auxiliary precursor is a straight-chain, branched, cyclic, or aromatic compound represented by Chemical Formula 1 below and the thin film precursor compound is represented by Chemical Formula 2 below.

AnBmXoYiZj, [Chemical Formula 1]

wherein A is carbon or silicon; B is hydrogen, an alkyl having 1 to 10 carbon atoms, a cycloalkyl having 3 to 10 carbon atoms, or an alkoxy having 1 to 10 carbon atoms; X includes one or more of fluorine (F), chlorine (Cl), bromine (Br), and iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

MₓL_{y}, [Chemical Formula 2]

wherein x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; y is an integer from 0 to 6; and L is H, C, N, O, F, P, S, Cl, Br, or I or a ligand consisting of a combination of two or more selected from the group consisting of H, C, N, O, F, P S, Cl, and Br.

The auxiliary precursor and the thin film precursor compound may have a weight ratio of 1:99 to 99:1.

The auxiliary precursor may include one or more selected from compounds represented by Chemical Formulas 3 to 14 below.

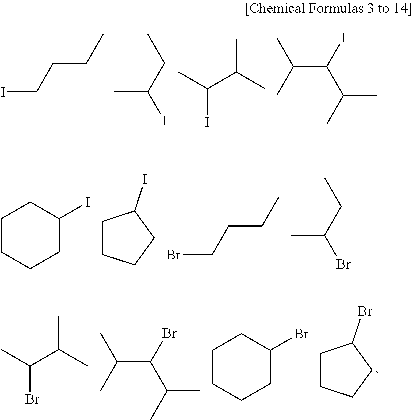

wherein a line is a bond, carbon is located at a point where bonds meet without indicating a separate element, and the number of hydrogen atoms satisfying a valence of the carbon is omitted.

The thin film precursor composition may be used in an atomic layer deposition (ALD) process, a plasma atomic layer deposition (PEALD) process, a chemical vapor deposition (CVD) process, or a plasma chemical vapor deposition (PECVD) process.

In accordance with still another aspect of the present invention, provided is a method of forming a thin film, the method including injecting the above-described thin film precursor composition into a chamber and adsorbing the thin film precursor composition on a surface of a loaded substrate.

The method of the present invention may include:
i) vaporizing the thin film precursor composition and adsorbing the thin film precursor composition onto a surface of a substrate loaded in a chamber;
ii) performing first purging of an inside of the chamber using a purge gas;
iii) supplying a reaction gas into the chamber; and
iv) performing second purging of the inside of the chamber using a purge gas.

The thin film precursor composition may be transferred into an ALD chamber, a CVD chamber, a PEALD chamber, or a PECVD chamber by a VFC method, a DLI method, or an LDS method.

An auxiliary precursor and a thin film precursor compound constituting the thin film precursor composition may be fed into the chamber at a feeding ratio (mg/cycle) of 1:0.1 to 1:20.

The reaction gas may be a reducing agent, a nitrifying agent, or an oxidizing agent.

In the method of forming a thin film, deposition temperature may be 200 to 700° C.

The thin film may be an oxide film, a nitride film, or a metal film.

The thin film may include a multilayer structure consisting of two or three layers.

In accordance with yet another aspect of the present invention, provided is a semiconductor substrate fabricated using the above-described method.

The semiconductor substrate may be a low-resistance metal gate interconnect, a high-aspect-ratio 3D metal-insulator-metal (MIM) capacitor, a DRAM trench capacitor, 3D gate-all-around (GAA), or 3D NAND.

### Advantageous Effects

According to the present invention, by appropriately controlling thin film growth rate by controlling deposition rate, even when a thin film is formed on a substrate having a complicated structure, an auxiliary precursor capable of improving step coverage and film quality can be provided.

In addition, the present invention has an effect of providing an auxiliary precursor for forming a thin film that does not interfere with adsorption of a thin film precursor compound during thin film formation due to reaction stability to the thin film precursor compound, is capable of preventing corrosion or deterioration by reducing process by-products, and is capable of improving the resistivity characteristics and electrical properties of a thin film by improving the crystallinity of the thin film. In addition, the present invention has an effect of providing a method of forming a thin film using the auxiliary precursor and a semiconductor substrate fabricated using the method.

### DESCRIPTION OF DRAWINGS

FIG. 1 includes diagrams showing the results of an experiment to check whether the auxiliary precursor of the present invention decomposes when mixing the auxiliary precursor with a thin film precursor compound. In the upper diagram, an ¹H-NMR spectrum for the auxiliary precursor alone used in Example 1 is shown. In the lower diagram, an ¹H-NMR spectrum for a mixture of the auxiliary precursor and the thin film precursor compound is shown.

### BEST MODE

Hereinafter, an auxiliary precursor, a thin film precursor composition, a method of forming a thin film using the thin film precursor composition, and a semiconductor substrate fabricated using the method according to the present invention will be described in detail.

The present inventors confirmed that, when adsorbing a thin film precursor compound on the surface of a substrate loaded in a chamber, when adsorbing the thin film precursor compound in combination with an auxiliary precursor having a specific structure that does not decompose, adsorption of the thin film precursor compound was not hindered, process by-products were reduced, corrosion or deterioration was prevented, the crystallinity of a thin film was improved, and as a result, the resistivity characteristics and electrical properties of the thin film were greatly improved. In addition, the present inventors confirmed that, when adsorbing a composition including a thin film precursor compound and a specific auxiliary precursor on the surface of a substrate loaded in a chamber, contrary to expectations, resistivity characteristics were greatly improved compared to a case of adsorbing the thin film precursor compound on the surface of a substrate loaded in a chamber and then adsorbing the auxiliary precursor on the surface or a case of adsorbing the auxiliary precursor on the surface of a substrate loaded in a chamber and then adsorbing the thin film precursor compound on the surface. Based on these results, the present inventors conducted further studies to complete the present invention.

As a preferred example, the method of forming a thin film may include step i) of vaporizing a thin film precursor composition including an auxiliary precursor and a thin film precursor mixture and adsorbing the composition on the surface of a substrate loaded in a chamber; step ii) of performing first purging of the inside of the chamber using a purge gas; step iii) of supplying a reaction gas into the chamber; and step iv) of performing second purging of the inside of the chamber using a purge gas. In this case, thin film growth rate may be controlled. In addition, even when deposition temperature increases during thin film formation, process by-products may be effectively removed, thereby improving the resistivity of a thin film and step coverage.

As another preferred example, the method of forming a thin film may include step i) of vaporizing an auxiliary precursor and a thin film precursor compound and adsorbing the auxiliary precursor and the thin film precursor compound on the surface of a substrate loaded in a chamber; step ii) of performing first purging of the inside of the chamber using a purge gas; step iii) of supplying a reaction gas into the chamber; and step iv) of performing second purging of the inside of the chamber using a purge gas. In this case, thin film growth rate may be controlled. In addition, even when deposition temperature increases during thin film formation, process by-products may be effectively removed, thereby improving the resistivity of a thin film and step coverage.

The thin film precursor composition including the auxiliary precursor and the thin film precursor compound may preferably be transferred to a chamber by a VFC method, a DLI method, or an LDS method, more preferably an LDS method.

The thin film precursor composition including the auxiliary precursor and the thin film precursor compound may preferably be used in an atomic layer deposition (ALD) process, a plasma atomic layer deposition (PEALD) process, a chemical vapor deposition (CVD) process, or a plasma chemical vapor deposition (PECVD) process, more preferably an atomic layer deposition (ALD) process or a plasma chemical vapor deposition (PECVD) process.

The thin film precursor compound may be represented by Chemical Formula 2 below.

MiₓL_{y} [Chemical Formula 2]

In Chemical Formula 2, x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; y is an integer from 0 to 6; and L is H, C, N, O, F, P, S, Cl, Br, or I or a ligand consisting of a combination of two or more selected from the group consisting of H, C, N, O, F, P, S, Cl, and Br. In this case, the desired effects of the present invention may be realized, and the resistivity of a thin film may be improved.

In addition, the thin film precursor composition of the present invention includes an auxiliary precursor, which is a straight-chain, branched, cyclic, or aromatic compound represented by Chemical Formula 1 below, and a thin film precursor compound represented by Chemical Formula 2 below.

AnBmXoYiZj [Chemical Formula 1]

In Chemical Formula 1, A is carbon or silicon; B is hydrogen, an alkyl having 1 to 10 carbon atoms, a cycloalkyl having 3 to 10 carbon atoms, or an alkoxy having 1 to 10 carbon atoms; X includes one or more of fluorine (F), chlorine (Cl), bromine (Br), and iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

MₓL_{y} [Chemical Formula 2]

In Chemical Formula 2, x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; y is an integer from 0 to 6; and L is H, C, N, O, F, P, S, Cl, Br, or I or a ligand consisting of a combination of two or more selected from the group consisting of H, C, N, O, F, P, S, Cl, and Br. In this case, the desired effects may be realized, and the resistivity of a thin film may be improved.

The weight ratio of the auxiliary precursor to the the thin film precursor compound may be 1:99 to 99:1, 1:90 to 90:1, 1:85 to 85:1, or 1:80 to 80:1.

For example, the auxiliary precursor may be a straight chain, branched, or cyclic compound represented by Chemical Formula 1. In Chemical Formula 1, A is carbon or silicon; B is hydrogen, an alkyl having 1 to 10 carbon atoms, a cycloalkyl having 3 to 10 carbon atoms, or an alkoxy having 1 to 10 carbon atoms; X is fluorine (F), chlorine (Cl), bromine (Br), or iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, and resistivity may be improved.

X may be a halogen element, preferably fluorine, chlorine, bromine, or iodine, more preferably chlorine or bromine. Within this range, process by-products may be reduced, and the degree of adsorption to a substrate may be further increased. In addition, for example, X may be chlorine. In this case, thin film crystallinity may be improved, and side reactions may be suppressed, thereby reducing process by-products.

As another preferred example, in Chemical Formula 1, X may be iodine or bromine. In this case, the auxiliary precursor may be more suitable for processes requiring low temperature deposition.

As a preferred example, the auxiliary precursor may be a straight chain, branched, or cyclic compound represented by Chemical Formula 1. In Chemical Formula 1, A is carbon; B is hydrogen or an alkyl having 1 to 10 carbon atoms; X is bromine (Br) or iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, and resistivity may be improved.

As a preferred example, the auxiliary precursor may be a straight chain, branched, or cyclic compound represented by Chemical Formula 1. In Chemical Formula 1, A is carbon; B is hydrogen or an alkyl having 1 to 10 carbon atoms; X is bromine (Br) or iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are 0. In this case, the desired effects of the present invention may be effectively expressed, resistivity and thin film crystallinity may be improved, and side reactions may be suppressed, thereby increasing the effect of reducing process by-products.

As another preferred example, the auxiliary precursor includes a hydrocarbon compound including an electron acceptor terminal group. The hydrocarbon compound may be a material that is not reactive with the thin film precursor compound. In this case, when the auxiliary precursor is used, adsorption of the thin film precursor compound may not be hindered, process by-products may be reduced, and deposition rate may be adjusted to appropriately reduce thin film growth rate. Thus, even when a thin film is formed on a substrate having a complicated structure, step coverage and film quality may be improved, corrosion or deterioration may be prevented, the crystallinity of a thin film may be improved, and thus the resistivity characteristics and electrical properties of the thin film may be improved.

The hydrocarbon compound may preferably be a compound having a structure in which one or more selected from the group consisting of alkanes and cycloalkanes are replaced with an electron acceptor terminal group. In this case, reactivity and solubility may be low, and moisture may be easily controlled. In addition, when forming a thin film, step coverage may be improved in a high aspect ratio trench structure.

As a more preferred example, the hydrocarbon compound may include a C1 to C10 alkane or a C3 to C10 cycloalkane, preferably a C3 to C10 cycloalkane. In this case, reactivity and solubility may be reduced, and moisture management may be easy.

In the present disclosure, Cl, C3, and the like mean the carbon number.

The cycloalkane may preferably be a C3 to C10 monocycloalkane. Among the monocycloalkanes, cyclopentane exists in a liquid state at room temperature and has the highest vapor pressure, and thus is preferable in a vapor deposition process. However, the present invention is not limited thereto.

Unless otherwise specified, the term “electron acceptor terminal group” used in the present invention refers to a functional group that may provide improvement in film quality when combined with a thin film precursor compound.

For example, the electron acceptor terminal group may be an ortho-oriented or para-oriented deactivator.

Unless otherwise specified, the term “ortho-oriented or para-oriented deactivator” refers to a deactivator that exhibits orientation at the ortho or para position thereof when using a precursor compound having a benzene ring.

As another example, the electron acceptor terminal group may be an electron accepter having an electronegativity of 2.0 to 4.0, preferably 2.0 to 3.0.

Unless otherwise specified, when a precursor compound without a benzene ring is used, the compound may have a functional group that satisfies the corresponding electronegativity range.

As a specific example, the electron acceptor terminal group may be a halogen element, preferably fluorine, chlorine, bromine, or iodine, more preferably bromine or iodine. Within this range, the effect of reducing process by-products and improving step coverage may further increase. In addition, X may be, for example iodine. In this case, the auxiliary precursor may be more suitable for processes requiring low temperature deposition. In particular, iodine may be used alone as X. In this case, the film quality of a thin film may be further improved by preventing excessive increase in impurities.

When the reactivity between the hydrocarbon compound and the thin film precursor compound is measured, an H-NMR spectrum measured before mixing the hydrocarbon compound and the thin film precursor compound is compared with an H-NMR spectrum measured after pressurizing for 1 hour a mixture obtained by mixing the hydrocarbon compound and the thin film precursor compound in a molar ratio of 1:1. At this time, when the integrated value of the generated NMR peaks is referred to as the amount of impurities, the amount (%) of the impurities is less than 0.1%. Thus, when the auxiliary precursor is used, adsorption of the thin film precursor compound may not be hindered, process by-products may be reduced, and deposition rate may be adjusted to appropriately reduce thin film growth rate. Thus, even when a thin film is formed on a substrate having a complicated structure, step coverage and film quality may be improved, corrosion or deterioration may be prevented, the crystallinity of a thin film may be improved, and thus the resistivity characteristics and electrical properties of the thin film may be improved.

Due to the above-mentioned reactivity, the auxiliary precursor easily controls the viscosity or vapor pressure of the thin film precursor compound, but does not interfere with the behavior of the thin film precursor compound.

For example, the hydrocarbon compound exhibiting the above-described reactivity and including an electron acceptor terminal group may be a halogen-substituted straight-chain or branched alkane compound or cycloalkane compound.

As a specific example, the hydrocarbon compound may include one or more selected from the group consisting of 1-iodobutane, 2-iodobutane, 2-iodo-3-methyl butane, 3-iodo-2,4-dimethyl pentane, cyclohexyl iodide, cyclopentyl iodide, 1-bromobutane, 2-bromobutane, 2-bromo-3-methyl butane, 3-bromo-2,4-dimethyl pentane, cyclohexyl bromide, and cyclopentyl bromide, preferably one or more selected from the group consisting of 1-iodobutane and 2-iodobutane. In this case, as the auxiliary precursor, the hydrocarbon compound may effectively protect the surface of a substrate and may effectively remove process by-products without interfering with adsorption of the thin film precursor compound.

As described above, the hydrocarbon compound may include halogen-substituted hydrocarbons, as a specific example, compounds represented by Chemical Formulas 3 to 14 below. The compounds represented by Chemical Formulas 3 to 14 may be selected independently or used in combination.

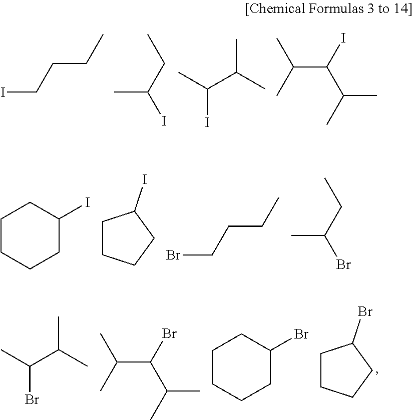

In Chemical Formulas 3 to 14, a line is a bond, carbon is located at a point where bonds meet without indicating a separate element, and the number of hydrogen atoms satisfying a valence of the carbon is omitted.

The auxiliary precursor is preferably used in an atomic layer deposition (ALD) process, a plasma atomic layer deposition (PEALD) process, a chemical vapor deposition (CVD) process, or a plasma chemical vapor deposition (PECVD) process. In this case, the auxiliary precursor may effectively protect the surface of a substrate without interfering with adsorption of the thin film precursor compound, and process by-products may be effectively removed.

Preferably, the auxiliary precursor may be in a liquid state at room temperature (22° C.) and may have a density of 0.8 to 2.5 g/cm³ or 0.8 to 1.7 g/cm³, a vapor pressure (20° C.) of 0.1 to 300 mmHg or 1 to 300 mmHg, and a water solubility (25° C.) of 200 mg/L or less. Within this range, step coverage and the thickness uniformity and quality of a thin film may be improved.

More preferably, the auxiliary precursor may have a density of 0.75 to 2.0 g/cm³ or 0.8 to 1.7 g/cm³, a vapor pressure (20° C.) of 1 to 260 mmHg, and a water solubility (25° C.) of 160 mg/L or less. Within this range, step coverage and the thickness uniformity and quality of a thin film may be improved.

In addition, as another preferred example, the method of forming a thin film of the present invention includes a step of injecting the thin film precursor composition into an ALD chamber and adsorbing the thin film precursor composition on the surface of a loaded substrate. In this case, thin film growth rate may be increased appropriately, and process by-products generated during thin film formation may be effectively removed, thereby reducing impurities in a thin film and greatly improving crystallinity.

In the method of forming a thin film, a reducing agent, a nitrifying agent, or an oxidizing agent is used as the reaction gas.

For example, in the method of forming a thin film, deposition temperature may be 200 to 700° C., preferably 250 to 500° C., as a specific example, 250 to 450° C., 250 to 320° C., 380 to 420° C., or 400 to 450° C. Within this range, thin film resistivity and step coverage may be greatly improved.

In addition, the thin film precursor composition of the present invention may include an auxiliary precursor, which is a straight-chain, branched, cyclic, or aromatic compound represented by Chemical Formula 1 below, and a thin film precursor compound represented by Chemical Formula 2 below.

AnBmXoYiZj [Chemical Formula 1]

In Chemical Formula 1, A is carbon or silicon; B is hydrogen or an alkyl having 1 to 10 carbon atoms; X includes one or more of fluorine (F), chlorine (Cl), bromine (Br), and iodine (I); Y and Z independently include one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

MₓL_{y} [Chemical Formula 2]

In Chemical Formula 2, x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; y is an integer from 1 to 6; and L is H, C, N, O, F, P, S, Cl, Br, or I or a ligand consisting of a combination of two or more selected from the group consisting of H, C, N, O, F, P, S, Cl, and Br. In this case, the desired effects of the present invention may be achieved, and high resistivity may be realized.

In Chemical Formula 2, M is titanium, tungsten, molybdenum, silicon, hafnium, zirconium, indium, or germanium, preferably titanium, tungsten, molybdenum, or silicon.

In Chemical Formula 2, L is a halogen element, preferably fluorine, chlorine, bromine, or iodine, more preferably chlorine or bromine. Within this range, process by-products may be reduced, and the degree of adsorption to a substrate may be further increased. In addition, L may be, for example, chlorine. In this case, thin film crystallinity may be improved, side reactions may be suppressed, and the effect of reducing process by-products may be greatly increased.

The compound represented by Chemical Formula 2 is a halogen-substituted tertiary alkyl compound. As a specific example, the halogen-substituted tertiary alkyl compound may include one or more selected from the group consisting of tetrachlorotitanium, 2-chloro-3-methyltitanium, 2-chloro-2-methyltitanium, tetrabromotitanium, 3-bromo-3-methyltitanium, 3-bromo-3-methyltitanium, tetrachlorotitanium, 2-chloro-3-methyltungsten, 2-chloro-2-methyltungsten, tetrabromotungsten, 3-bromo-3-methyltungsten, 3-bromo-3-methyltungsten, tetrachloromolybdenum, 2-chloro-3-methylmolybdenum, 2-chloro-2-methylmolybdenum, tetrabromomolybdenum, 3-bromo-3-methylmolybdenum, 3-bromo-3-methylmolybdenum, tetrachlorohafnium, 2-chloro-3-methylhafnium, 2-chloro-2-methylhafnium, tetrabromohafnium, 3-bromo-3-methylhafnium, 3-bromo-3-methylhafnium, tetrachlorohafnium, 2-chloro-3-methylzirconium, 2-chloro-2-methylzirconium, tetrabromozirconium, 3-bromo-3-methylzirconium, 3-bromo-3-methylzirconium, tetrachloroindium, 2-chloro-3-methylindium, 2-chloro-2-methylindium, tetrabromoindium, 3-bromo-3-methylindium, and 3-bromo-3-methylindium. In this case, process by-products may be efficiently removed, step coverage may be improved, and adsorption to a substrate may be promoted.

Unless otherwise specified, the term “conductive compound” used in the present invention refers to a material that has electron donors or acceptors and has conductivity, and may affect depending on the structure and charge transfer oxidation state thereof.

The compound represented by Chemical Formula 2 or the conductive compound is described as a specific example, but the present invention is not limited thereto. A thin film precursor compound typically used in an atomic layer deposition (ALD) method may be used without particular limitation.

As a specific example, the thin film precursor compound may include one or more selected from the group consisting of a metal thin film precursor compound, a metal oxide thin film precursor compound, a metal nitride thin film precursor compound, and a silicon nitride thin film precursor compound, and the metal may preferably include one or more selected from the group consisting of tungsten, cobalt, chromium, aluminum, hafnium, vanadium, niobium, germanium, lanthanides, actinoids, gallium, tantalum, zirconium, ruthenium, copper, titanium, nickel, iridium, molybdenum, platinum, and ruthenium.

For example, the metal film precursor, the metal oxide film precursor, and the metal nitride film precursor may independently include one or more selected from the group consisting of metal halides, metal alkoxides, alkyl metal compounds, metal amino compounds, metal carbonyl compounds, and substituted or unsubstituted cyclopentadienyl metal compounds, without being limited thereto.

For example, the metal oxide film precursor may be selected from the group consisting of PtO, PtO₂, RuO₂, IrO₂, SrRuO₃, BaRuO₃, and CaRuO₃.

As a specific example, the metal film precursor, the metal oxide film precursor, and the metal nitride film precursor may independently include one or more selected from the group consisting of tetrachlorotitanium, tetrachlorogemanium, tetrachlorotin, tris(isopropyl)ethylmethyl aminogermanium, tetraethoxylgermanium, tetramethyl tin, tetraethyl tin, bisacetylacetonate tin, trimethylaluminum, tetrakis(dimethylamino)germanium, bis(n-butylamino) germanium, tetrakis(ethylmethylamino)tin, tetrakis(dimethylamino)tin, dicobalt octacarbonyl (Co₂(CO)₈), biscyclopentadienylcobalt (Cp2Co), cobalt tricarbonyl nitrosyl (Co(CO)₃NO), and cabalt dicarbonyl cyclopentadienyl (CpCo(CO)₂), without being limited thereto.

For example, the silicon nitride film precursor may include one or more selected from the group consisting of SiH₄, SiCl₄, SiF₄, SiCl₂H₂, Si₂Cl₆, TEOS, DIPAS, BTBAS, (NH₂)Si(NHMe)₃, (NH₂)Si(NHEt)₃, (NH₂)Si(NHⁿPr)₃, (NH₂)Si(NHⁱPr)₃, (NH₂)Si(NHⁿBu)₃, (NH₂)Si(NHⁱBu)₃, (NH₂)Si(NH^{t}Bu)₃, (NMe₂)Si(NHMe)₃, (NMe₂)Si(NHEt)₃, (NMe₂)Si(NHⁿPr)₃, (NMe₂)Si(NHⁱPr)₃, (NMe₂)Si(NHⁿBu)₃, (NMe₂)Si(NHⁱBu)₃, (NMe₂)Si(NHⁿBu)₃, (NEt₂)Si(NHMe)₃, (NEt₂)Si(NHEt)₃, (NEt₂)Si(NHⁿPr)₃, (NEt₂)Si(NHⁱPr)₃, (NEt₂)Si(NHⁿBu)₃, (NEt₂)Si(NHⁱBu)₃, (NEt₂)Si(NH^{t}Bu)₃, (NⁿPr₂)Si(NHMe)₃, (NⁿPr₂)Si(NHEt)₃, (NⁿPr₂)Si(NHⁿPr)₃, (NⁿPr₂)Si(NHⁱPr)₃, (NⁿPr₂)Si(NHⁿBu)₃, (NⁿPr₂)Si(NHⁱBu)₃, (NⁿPr₂)Si(NH^{t}Bu)₃, (NⁱPr₂)Si(NHMe)₃, (NⁱPr₂)Si(NHEt)₃, (NⁱPr₂)Si(NHⁿPr)₃, (NⁱPr₂)Si(NHⁱPr)₃, (NⁱPr₂)Si(NHⁿBu)₃, (NⁱPr₂)Si(NHⁱBu)₃, (NⁱPr₂)Si(NH^{t}Bu)₃, (NⁿBu₂)Si(NHMe)₃, (NⁿBu₂)Si(NHEt)₃, (NⁿBu₂)Si(NHⁿPr)₃, (NⁿBu₂)Si(NHⁱPr)₃, (NⁿBu₂)Si(NHⁿBu)₃, (NⁿBu₂)Si(NHⁱBu)₃, (NⁿBu₂)Si(NH^{t}Bu)₃, (NⁱBu₂)Si(NHMe)₃, (NⁱBu₂)Si(NHEt)₃, (NⁱBu₂)Si(NHⁿPr)₃, (NⁱBu₂)Si(NHⁱPr)₃, (NⁱBu₂)Si(NHⁿBu)₃, (NⁱBu₂)Si(NHⁱBu)₃, (NⁱBu₂)Si(NH^{t}Bu)₃, (N^{t}Bu₂)Si(NHMe)₃, (N^{t}Bu₂)Si(NHEt)₃, (N^{t}Bu₂)Si(NHⁿPr)₃, (N^{t}Bu₂)Si(NHⁱPr)₃, (N^{t}Bu₂)Si(NHⁿBu)₃, (N^{t}Bu₂)Si(NHⁱBu)₃, (N^{t}Bu₂)Si(NH^{t}Bu)₃, (NH₂)₂Si(NHMe)₂, (NH₂)₂Si(NHEt)₂, (NH₂)₂Si(NHⁿPr)₂, (NH₂)₂Si(NHⁱPr)₂, (NH₂)₂Si(NHⁿBu)₂, (NH₂)₂Si(NHⁱBu)₂, (NH₂)₂Si(NH^{t}Bu)₂, (NMe₂)₂Si(NHMe)₂, (NMe₂)₂Si(NHEt)₂, (NMe₂)₂Si(NHⁿPr)₂, (NMe₂)₂Si(NHⁱPr)₂, (NMe₂)₂Si(NHⁿBu)₂, (NMe₂)₂Si(NHⁱBu)₂, (NMe₂)₂Si(NH^{t}Bu)₂, (NEt₂)₂Si(NHMe)₂, (NEt₂)₂Si(NHEt)₂, (NEt₂)₂Si(NHⁿPr)₂, (NEt₂)₂Si(NHⁱPr)₂, (NEt₂)₂Si(NHⁿBu)₂, (NEt₂)₂Si(NHⁱBu)₂, (NEt₂)₂Si(NH^{t}Bu)₂, (NⁿPr₂)₂Si(NHMe)₂, (NⁿPr₂)₂Si(NHEt)₂, (NⁿPr₂)₂Si(NHⁿPr)₂, (NⁿPr₂)₂Si(NHⁱPr)₂, (NⁿPr₂)₂Si(NHⁿBu)₂, (NⁿPr₂)₂Si(NHⁱBu)₂, (NⁿPr₂)₂Si(NH^{t}Bu)₂, (NⁱPr₂)₂Si(NHMe)₂, (NⁱPr₂)₂Si(NHEt)₂, (NⁱPr₂)₂Si(NHⁿPr)₂, (NⁱPr₂)₂Si(NHⁱPr)₂, (NⁱPr₂)₂Si(NHⁿBu)₂, (NⁱPr₂)₂Si(NHⁱBu)₂, (NⁱPr₂)₂Si(NH^{t}Bu)₂, (NⁿBu₂)₂Si(NHMe)₂, (NⁿBu₂)₂Si(NHEt)₂, (NⁿBu₂)₂Si(NHⁿPr)₂, (NⁿBu₂)₂Si(NHⁱPr)₂, (NⁿBu₂)₂Si(NHⁿBu)₂, (NⁿBu₂)₂Si(NHⁱBu)₂, (NⁿBu₂)₂Si(NH^{t}Bu)₂, (NⁱBu₂)₂Si(NHMe)₂, (NⁱBu₂)₂Si(NHEt)₂, (NⁱBu₂)₂Si(NHⁿPr)₂, (NⁱBu₂)₂Si(NHⁱPr)₂, (NⁱBu₂)₂Si(NHⁿBu)₂, (NⁱBu₂)₂Si(NHⁱBu)₂, (NⁱBu₂)₂Si(NH^{t}Bu)₂, (N^{t}Bu₂)₂Si(NHMe)₂, (N^{t}Bu₂)₂Si(NHEt)₂, (N^{t}Bu₂)₂Si(NHⁿPr)₂, (N^{t}Bu₂)₂Si(NHⁱPr)₂, (N^{t}Bu₂)₂Si(NHⁿBu)₂, (N^{t}Bu₂)₂Si(NHⁱBu)₂, (N^{t}Bu₂)₂Si(NH^{t}Bu)₂, Si(HNCH₂CH₂NH)₂, Si(MeNCH₂CH₂NMe)₂, Si(EtNCH₂CH₂NEt)₂, Si(ⁿPrNCH₂CH₂NⁿPr)₂, Si(ⁱPrNCH₂CH₂NⁱPr)₂, Si(ⁿBuNCH₂CH₂NⁿBu)₂, Si(ⁱBuNCH₂CH₂NⁱBu)₂, Si(^{t}BuNCH₂CH₂N^{t}Bu)₂, Si(HNCHCHNH)₂, Si(MeNCHCHNMe)₂, Si(EtNCHCHNEt)₂, Si(ⁿPrNCHCHNⁿPr)₂, Si(ⁱPrNCHCHNⁱPr)₂, Si(ⁿBuNCHCHNⁿBu)₂, Si(ⁱBuNCHCHNⁱBu)₂, Si(^{t}BuNCHCHN^{t}Bu)₂, (HNCHCHNH)Si(HNCH₂CH₂NH), (MeNCHCHNMe)Si(MeNCH₂CH₂NMe), (EtNCHCHNEt)Si(EtNCH₂CH₂NEt), (ⁿPrNCHCHNⁿPr)Si(ⁿPrNCH₂CH₂NⁿPr), (ⁱPrNCHCHNⁱPr)Si(ⁱPrNCH₂CH₂NⁱPr), (ⁿBuNCHCHNⁿBu)Si(ⁿBuNCH₂CH₂NⁿBu), (ⁱBuNCHCHNⁱBu)Si(ⁱBuNCH₂CH₂NⁱBu), (^{t}BuNCHCHN^{t}Bu)Si(^{t}BuNCH₂CH₂N^{t}Bu), (NH^{t}Bu)₂Si(HNCH₂CH₂NH), (NH^{t}Bu)₂Si(MeNCH₂CH₂NMe), (NH^{t}Bu)₂Si(EtNCH₂CH₂NEt), (NH^{t}Bu)₂Si(ⁿPrNCH₂CH₂NⁿPr), (NH^{t}Bu)₂Si(ⁱPrNCH₂CH₂NⁱPr), (NH^{t}Bu)₂Si(ⁿBuNCH₂CH₂NⁿBu), (NH^{t}Bu)₂Si(ⁱBuNCH₂CH₂NⁱBu), (NH^{t}Bu)₂Si(^{t}BuNCH₂CH₂N^{t}Bu), (NH^{t}Bu)₂Si(HNCHCHNH), (NH^{t}Bu)₂Si(MeNCHCHNMe), (NH^{t}Bu)₂Si(EtNCHCHNEt), (NH^{t}Bu)₂Si(ⁿPrNCHCHNⁿPr), (NH^{t}Bu)₂Si(ⁱPrNCHCHNⁱPr), (NH^{t}Bu)₂Si(ⁿBuNCHCHNⁿBu), (NH^{t}Bu)₂Si(ⁱBuNCHCHNⁱBu), (NH^{t}Bu)₂Si(^{t}BuNCHCHN^{t}Bu), (ⁱPrNCH₂CH₂NⁱPr)Si(NHMe)₂, (ⁱPrNCH₂CH₂NⁱPr)Si(NHEt)₂, (ⁱPrNCH₂CH₂NⁱPr)Si(NHⁿPr)₂, (ⁱPrNCH₂CH₂NⁱPr)Si(NHⁱPr)₂, (ⁱPrNCH₂CH₂NⁱPr)Si(NHⁿBu)₂, (ⁱPrNCH₂CH₂NⁱPr)Si(NHⁱBu)₂, (ⁱPrNCH₂CH₂NⁱPr)Si(NHⁱBu)₂, (ⁱPrNCHCHNⁱPr)Si(NHMe)₂, (ⁱPrNCHCHNⁱPr)Si(NHEt)₂, (ⁱPrNCHCHNⁱPr)Si(NHⁿPr)₂, (ⁱPrNCHCHNⁱPr)Si(NHⁱPr)₂, (ⁱPrNCHCHNⁱPr)Si(NHⁱBu)₂, (ⁱPrNCHCHNⁱPr)Si(NHⁱBu)₂, and (ⁱPrNCHCHNⁱPr)Si(NH^{t}Bu)₂, without being limited thereto.

Here, ⁿPr means n-propyl, ⁱPr means iso-propyl, ⁿBu means n-butyl, ⁱBu means iso-butyl, and ^{t}Bu means tert-butyl.

As a preferred example, the thin film precursor compound may include one or more selected from the group consisting of TiCl₄, (Ti(CpMe₅)(OMe)₃), Ti(CpMe₃)(OMe)₃, Ti(OMe)₄, Ti(OEt)₄, Ti(OtBu)₄, Ti(CpMe) (OiPr)₃, TTIP(Ti(OiPr)₄, TDMAT (Ti(NMe₂)₄), Ti(CpMe) {N(Me₂)₃}, Pt, Ru, Ir, PtO, PtO₂, RuO₂, IrO₂, SrRuO₃, BaRuO₃, and CaRuO₃. In this case, the required effects of the present invention may be fully achieved.

The titanium tetrahalide may be used as a metal precursor of a composition for forming a thin film. For example, the titanium tetrahalide may be at least one selected from the group consisting of TiF₄, TiCl₄, TiBr₄, and TiI₄. As a preferred example, considering economic feasibility, the titanium tetrahalide is TiCl₄, but the present invention is not limited thereto.

Since the titanium tetrahalide does not decompose at room temperature due to excellent thermal stability thereof and exists in a liquid state, the titanium tetrahalide may be used as a precursor for depositing a thin film according to atomic layer deposition (ALD).

For example, the thin film precursor compound may be fed into a chamber after being mixed with a non-polar solvent (excluding non-polar solvents that overlap with hydrocarbon compounds). In this case, the viscosity of the thin film precursor compound or vapor pressure may be easily adjusted.

The non-polar solvent may preferably include one or more selected from the group consisting of alkanes and cycloalkanes. In this case, step coverage may be improved even when deposition temperature increases when forming a thin film while containing an organic solvent having low reactivity and solubility and capable of easy moisture management.

As a more preferred example, the non-polar solvent may include a C1 to C10 alkane or a C3 to C10 cycloalkane, preferably a C3 to C10 cycloalkane. In this case, reactivity and solubility may be reduced, and moisture management may be easy.

In the present disclosure, Cl, C3, and the like mean the carbon number.

The cycloalkane may preferably be a C3 to C10 monocycloalkane. Among the monocycloalkanes, cyclopentane exists in a liquid state at room temperature and has the highest vapor pressure, and thus is preferable in a vapor deposition process. However, the present invention is not limited thereto.

For example, the non-polar solvent has a water solubility (25° C.) of 200 mg/L or less, preferably 50 to 200 mg/L, more preferably 135 to 175 mg/L. Within this range, reactivity to the thin film precursor compound may be low, and moisture management may be easy.

In the present disclosure, solubility may be measured without particular limitation according to measurement methods or standards commonly used in the art to which the present invention pertains. For example, solubility may be measured according to the HPLC method using a saturated solution.

Based on a total weight of the thin film precursor compound and the non-polar solvent, the non-polar solvent may be included in an amount of preferably 5 to 95% by weight, more preferably 10 to 90% by weight, still more preferably 40 to 90% by weight, most preferably 70 to 90% by weight.

When the content of the non-polar solvent exceeds the above range, impurities are generated to increase resistance and impurity levels in a thin film. When the content of the non-polar solvent is less than the above range, an effect of improving step coverage and reducing an impurity such as chlorine (Cl) ion due to addition of the solvent may be reduced.

Preferably, the compound or conductive compound represented by Chemical Formula 2 may be liquid at room temperature (22° C.), and may has a density of 0.8 to 2.5 g/cm³ or 0.8 to 1.5 g/cm³ and a vapor pressure (20° C.) of 0.1 to 300 mmHg or 1 to 300 mmHg. Within this range, step coverage and the thickness uniformity and quality of a thin film may be improved.

More preferably, the compound or conductive compound represented by Chemical Formula 2 may have a density of 0.75 to 2.0 g/cm³ or 0.8 to 1.8 g/cm³ and a vapor pressure (20° C.) of 1 to 260 mmHg. Within this range, step coverage and the thickness uniformity and quality of a thin film may be improved.

When the auxiliary precursor and the thin film precursor compound are fed into a chamber, the feeding ratio (mg/cycle) of the auxiliary precursor to the the thin film precursor compound may be preferably 1:0.1 to 1:20, more preferably 1:0.2 to 1:15, still more preferably 1:0.5 to 1:12, still more preferably 1:0.7 to 1:10. Within this range, the effect of improving step coverage and the effect of reducing process by-products may be greatly increased.

The precursor composition consisting of the auxiliary precursor and the thin film precursor compound is preferably used in an atomic layer deposition (ALD) process, a plasma atomic layer deposition (PEALD) process, a chemical vapor deposition (CVD) process, or a plasma chemical vapor deposition (PECVD) process. In this case, process by-products may be significantly reduced, step coverage may be excellent, thin film density may be improved, and the electrical properties of a thin film may be excellent.

The method of forming a thin film of the present invention includes a step of injecting the precursor composition into a chamber and adsorbing the precursor composition on the surface of a loaded substrate. In this case, side reactions may be reduced during thin film formation, thin film growth rate may be controlled, process by-products in a thin film may be reduced, corrosion or deterioration may be prevented, and the crystallinity of a thin film may be improved. Thus, even when a thin film is formed on a substrate having a complicated structure, step coverage and the electrical properties of the thin film may be greatly improved.

In the step of adsorbing the precursor composition on the surface of a substrate, feeding time for the precursor composition is preferably 0.01 to 10 seconds, more preferably 0.02 to 5 seconds, still more preferably 0.04 to 3 seconds, still more preferably 0.05 to 2 seconds per cycle. Within this range, thin film growth rate may be reduced, and step coverage and economics may be excellent.

In the present disclosure, the feeding time for the precursor composition is based on a chamber volume of 15 to 20 L and a flow rate of 0.5 to 100 mg/s, more specifically, a chamber volume of 18 L and a flow rate of 1 to 25 mg/s.

As a preferred example, the method of forming a thin film may include step i) of vaporizing the precursor composition and adsorbing the precursor composition on the surface of a substrate loaded in a chamber; step ii) of performing first purging of the inside of the chamber using a purge gas; step iii) of supplying a reaction gas into the chamber; and step iv) of performing second purging of the inside of the chamber using a purge gas. At this time, steps i) to iv) may be performed as a unit cycle and, the cycle may be repeated until a thin film having a desired thickness is obtained. In the cycle, when the auxiliary precursor of the present invention and the thin film precursor compound are fed at the same time and adsorbed to a substrate, even when deposited at low temperature, process by-products may be effectively removed, the resistivity of a thin film may be improved, and step coverage may be greatly improved.

As a preferred example, according to the method of forming a thin film of the present invention, in one cycle, the auxiliary precursor of the present invention and the thin film precursor compound may be fed at the same time, and the auxiliary precursor and the thin film precursor compound may be adsorbed on the substrate. In this case, even when a thin film is deposited at low temperatures, thin film growth rate may be appropriately reduced, thereby greatly reducing process by-products and greatly improving step coverage. In addition, the crystallinity of a thin film may be increased, thereby improving the resistivity of the thin film. In addition, even when the thin film is used in a semiconductor device having a high aspect ratio, due to improvement of the thickness uniformity of the thin film, the reliability of the semiconductor device may be secured.

For example, according to the method of forming a thin film, when depositing the thin film precursor compound and simultaneously adsorbing the auxiliary precursor, when necessary, the unit cycle may be repeated 1 to 99,999 times, preferably 10 to 10,000 times, more preferably 50 to 5,000 times, still more preferably 100 to 2,000 times. Within this range, a thin film having a desired thickness may be obtained, and the effect of improving physical properties including resistivity to be achieved in the present invention may be sufficiently obtained.

In addition, as shown in comparative examples to be described later, when the auxiliary precursor is adsorbed before deposition of the thin film precursor compound, or when the auxiliary precursor is adsorbed after deposition of the thin film precursor compound, the effect of improving physical properties including resistivity, which is obtained in the case of simultaneously adding and depositing the auxiliary precursor and the thin film precursor compound, may not be obtained.

When the auxiliary precursor and the thin film precursor compound are adsorbed on a substrate at the same time, in the step of purging the non-adsorbed precursor composition, the amount of a purge gas introduced into the chamber is not particularly limited as long as the purge gas is sufficient to remove the non-adsorbed precursor composition. For example, the amount of a purge gas may be 10 to 100,000 times, preferably 50 to 50,000 times, more preferably 100 to 10,000 times. Within this range, the non-adsorbed precursor composition may be sufficiently removed. Thus, a thin film may be formed uniformly, and deterioration of film quality may be prevented. Here, the feeding amounts of the purge gas and the precursor composition are based on one cycle. The volume of the precursor composition is the volume of the vaporized thin film precursor composition.

As a specific example, when the precursor composition is injected at a flow rate of 1.66 mL/s and an injection time of 0.5 sec (per cycle) and the purge gas is injected at a flow rate of 166.6 mL/s and an injection time of 3 sec (per cycle) in the step of purging the non-adsorbed precursor composition, the injection amount of the purge gas is 602 times that of the thin film precursor composition.

In addition, for example, in the purging step performed immediately after the reaction gas supply step, based on the volume of the reaction gas introduced into the chamber, the amount of the purge gas introduced into the chamber may be 10 to 10,000 times, preferably 50 to 50,000 times, more preferably 100 to 10,000 times. Within this range, the desired effects may be fully achieved. Here, the input amounts of the purge gas and reaction gas are each based on one cycle.

The thin film precursor composition and the thin film precursor compound may preferably be transferred into an ALD chamber, a CVD chamber, a PEALD chamber, or a PECVD chamber by a VFC method, a DLI method, or an LDS method. More preferably, the thin film precursor composition and the thin film precursor compound are transferred to an ALD chamber by an LDS method.

When the auxiliary precursor and the thin film precursor compound constituting the precursor composition are fed into a chamber, the feeding ratio (mg/cycle) of the auxiliary precursor to the thin film precursor compound may be preferably 1:0.1 to 1:20, more preferably 1:0.2 to 1:15, still more preferably 1:0.5 to 1:12, still more preferably 1:0.7 to 1:10. Within this range, the effect of improving step coverage and the effect of reducing process by-products may be greatly increased.

For example, in the method of forming a thin film, when the precursor composition is used, the degree of improvement in resistivity (μΩ·cm) calculated by Equation 1 below is −51% or less, preferably −51% to −10%. Within this range, step coverage, resistivity characteristics, and the thickness uniformity of a thin film may be excellent.

Degree of improvement in resistivity (%)=[(Resistivity when auxiliary precursor is used−Resistivity when no auxiliary precursor is used)/Resistivity when no auxiliary precursor is used]×100 [Equation 1]

In Equation 1, the degree of improvement in resistivity when an auxiliary precursor is used and the degree of improvement in resistivity when no auxiliary precursor is used mean the conductivity properties, i.e., resistivity (μΩ·cm), of each case. For example, when the resistivity is measured, surface resistance is measured using a four-point probe, and then the resistivity is obtained based on the thickness value of a thin film.

In Equation 1, “when an auxiliary precursor is used” means a case of adsorbing the auxiliary precursor and the thin film precursor compound on a substrate at the same time in the thin film deposition process to form a thin film. “When no auxiliary precursor is used” means a case of adsorbing the thin film precursor compound on a substrate without using the auxiliary precursor in the thin film deposition process to form a thin film.

According to the method of forming a thin film, when residual halogen intensity (c/s) in a thin film having a thickness of 100 Å is measured according to XPS, the residual halogen intensity (c/s) may be preferably 100,000 or less, more preferably 70,000 or less, still more preferably 50,000 or less, still more preferably 10,000 or less, as a preferred example, 5,000 or less, still more preferably 1,000 to 4,000, still more preferably 1,000 to 3,800. Within this range, the effect of preventing corrosion and deterioration may be excellent.

In the present disclosure, purging may be performed at preferably 1,000 to 50,000 sccm (Standard Cubic Centimeter per Minute), more preferably 2,000 to 30,000 sccm, still more preferably 2,500 to 15,000 sccm. Within this range, a thin film growth rate per cycle may be controlled appropriately, and film quality may be improved by depositing a thin film in an atomic monolayer or an atomic monolayer-like layer.

The atomic layer deposition (ALD) process is very advantageous in fabricating integrated circuits (ICs) requiring a high aspect ratio, and in particular, due to a self-limiting thin film growth mechanism, excellent conformality and uniformity and precise thickness control may be achieved.

For example, in the method of forming a thin film, the deposition temperature may be 50 to 800° C., preferably 200 to 700° C., more preferably 250 to 500° C., still more preferably 250 to 600° C. Within this range, an effect of growing a thin film having excellent film quality may be obtained while implementing ALD process characteristics.

For example, in the method of forming a thin film, the deposition pressure may be 0.01 to 20 Torr, preferably 0.1 to 20 Torr, more preferably 0.1 to 10 Torr, most preferably 0.1 to 7 Torr. Within this range, a thin film having a uniform thickness may be obtained.

In the present disclosure, the deposition temperature and the deposition pressure may be temperature and pressure in a deposition chamber or temperature and pressure applied to a substrate in a deposition chamber.

The method of forming a thin film may preferably include a step of increasing temperature in a chamber to a deposition temperature before introducing the precursor composition into the chamber; and/or a step of performing purging by injecting an inert gas into a chamber before introducing the precursor composition into the chamber.

In addition, as a thin film-forming apparatus capable of implementing the method of forming a thin film, the present invention may include an thin film-forming apparatus including an ALD chamber, a first vaporizer for vaporizing an auxiliary precursor, a first transfer means for transferring the vaporized auxiliary precursor into the ALD chamber, a second vaporizer for vaporizing a thin film precursor compound, and a second transfer means for transferring the vaporized thin film precursor compound into the ALD chamber.

In addition, according to the present invention, the thin film-forming device may include a mixing means for mixing the vaporized auxiliary precursor and the vaporized thin film precursor compound. The precursor composition may be premixed and then transferred into the chamber.

Here, a vaporizer, a transfer means, and a mixing means commonly used in the art to which the present invention pertains may be used in the present invention without particular limitation.

As a specific example, the method of forming a thin film using the ALD process is described in detail as follows.

First, a substrate on which a thin film is to be formed is placed in a deposition chamber capable of performing atomic layer deposition.

The substrate may include a semiconductor substrate such as a silicon substrate or a silicon oxide substrate.

A conductive layer or an insulating layer may be further formed on the substrate.

To deposit a thin film on the substrate placed in the deposition chamber, the auxiliary precursor and the thin film precursor compound or a mixture of the thin film precursor compound and a non-polar solvent are prepared.

Then, the prepared auxiliary precursor and the prepared thin film precursor compound or mixture (composition for forming a thin film) of the thin film precursor compound and a non-polar solvent are injected into a vaporizer, converted into a vapor phase, transferred to a deposition chamber, and adsorbed on the substrate. Alternatively, after preparing the composition for forming a thin film in advance, the composition is converted into a vapor phase using a vaporizer, transferred to a deposition chamber, and adsorbed on the substrate. Then, the non-adsorbed precursor composition (composition for forming a thin film) is purged.

According to one embodiment of the present invention, since an auxiliary precursor that does not react with the thin film precursor compound is used, most of the auxiliary precursor may be removed during purging.

In the present disclosure, for example, when the auxiliary precursor and the thin film precursor compound (composition for forming a thin film) are transferred to a deposition chamber, a vapor flow control (VFC) method using a mass flow control (MFC) method, or a liquid delivery system (LDS) using a liquid mass flow control (LMFC) method may be used. Preferably, the LDS method is used.

In this case, one selected from argon (Ar), nitrogen (N₂), and helium (He) or a mixed gas of two or more thereof may be used as a transport gas or a diluent gas for moving the auxiliary precursor and the thin film precursor compound to the substrate, but the present invention is not limited thereto.

In the present disclosure, for example, an inert gas may be used as the purge gas, and the transport gas or the dilution gas may be preferably used as the purge gas.

Next, a reaction gas is supplied. Reaction gases commonly used in the art to which the present invention pertains may be used as the reaction gas of the present invention without particular limitation. Preferably, the reaction gas may include a reducing agent, a nitrifying agent, or an oxidizing agent. A metal thin film is formed by reacting the reducing agent with the thin film precursor compound adsorbed on the substrate, a metal nitride thin film is formed by the nitrifying agent, and a metal oxide thin film is formed by the oxidizing agent.

Preferably, the reducing agent may be an ammonia gas (NH₃) or a hydrogen gas (H₂), the nitrifying agent may be a nitrogen gas (N₂), a hydrazine gas (N₂H₄), or a mixture of a nitrogen gas and a hydrogen gas, and the oxidizing agent may include one or more selected from the group consisting of H₂O, H₂O₂, O₂, O₃, and N₂O.

Next, the unreacted residual reaction gas is purged using an inert gas. Accordingly, in addition to the excess reaction gas, by-products may also be removed.

As described above, in the method of forming a thin film, the step of adsorbing a precursor composition on a substrate, the step of purging the unadsorbed precursor composition, the step of supplying a reaction gas, and the step of purging the remaining reaction gas may be set as a unit cycle. The unit cycle may be repeatedly performed to form a thin film having a desired thickness.

For example, the unit cycle may be performed 1 to 99,999 times, preferably 10 to 1,000 times, more preferably 50 to 5,000 times, still more preferably 100 to 2,000 times. Within this range, the desired thin film properties may be effectively implemented.

In addition, the present invention provides a semiconductor substrate. The semiconductor substrate is fabricated using the method of forming a thin film of the present invention. In this case, the step coverage, thickness uniformity, resistivity characteristics, density, and electrical properties of a thin film may be excellent.

Preferably, the formed thin film has a thickness of nm or less, a resistivity value of 5 to 400 μΩ·cm based on a thin film thickness of 10 nm, a halogen content of 10,000 ppm or less, and a step coverage of 80% or more. Within this range, the thin film has excellent performance as a diffusion barrier and may reduce corrosion of metal wiring materials, but the present invention is not limited thereto.

For example, the thin film may have a thickness of 1 to 30 nm, preferably 2 to 27 nm, more preferably 3 to 25 nm, still more preferably 5 to 23 nm. Within this range, thin film properties may be excellent.

For example, the thin film may have a resistivity value of 5 to 400 μΩ·cm, preferably 5 to 360 μΩ·cm based on a thin film thickness of 10 nm. Within this range, thin film properties may be excellent.

The thin film may have a halogen content of preferably 10,000 ppm or less or 1 to 8,000 ppm, still more preferably 1 to 5,000 ppm, still more preferably 1 to 1000 ppm. Within this range, thin film properties may be excellent, and corrosion of metal wiring materials may be reduced. Here, for example, halogens remaining in the thin film may include Cl₂, Cl, and Cl⁻. As the amount of halogens remaining in the thin film decreases, film quality may be increased.

For example, the thin film may have a step coverage of 80% or more, preferably 90% or more, more preferably 95% or more. Within this range, even a thin film having a complex structure may be easily deposited on a substrate. Thus, the thin film may be applied to next-generation semiconductor devices.

For example, the formed thin film may include one or more selected from the group consisting of a titanium nitride film (TiₓN_{y}, 0<x≤1.2, 0<y≤1.2, preferably 0.8≤x≤1, 0.8≤y≤1, more preferably x and y are 1) and a titanium oxide film (TiO₂), preferably a titanium nitride film. In this case, the thin film may be usefully used as a diffusion barrier, an etch stop film, or an electrode for semiconductor devices.

For example, when necessary, the thin film may have a multilayer structure consisting of two or three layers. As a specific example, the multilayer structure consisting of two layers may be a lower layer-middle layer structure, and the multilayer structure consisting of three layers may be a lower layer-middle layer-upper layer structure.

The lower layer may be a dielectric film. For example, the lower layer may be composed of one or more selected from the group consisting of SiO₂, MgO, Al₂O₃, CaO, ZrSiO₄, ZrO₂, HfSiO₄, Y₂O₃, HfO₂, LaLuO₂, LaAlO₃, BaZrO₃, SrZrO₃, SrTiO₃, BaTiO₃, Si₃N₄, SrO, La₂O₃, Ta₂O₅, BaO, and TiO₂.

For example, the middle layer may be composed of TiₓN_{y}, preferably TiN.

For example, the upper layer may be composed of one or more selected from the group consisting of W and Mo.

Hereinafter, the present invention will be described in more detail with reference to the following preferred examples and drawings. However, these examples and drawings are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

### Examples 1 to 6 and Comparative Examples 1 to 5

<Reactivity Test of Auxiliary Precursor and Thin Film Precursor Compound>

The reactivity of auxiliary precursors and thin film precursor compounds used in Examples 1 to 6 and Comparative Examples 1 to 5 below was tested.

The combinations shown in Table 1 below were selected as reactivity test subjects.

As a specific example, H-NMR was measured before mixing the thin film precursor compound and the auxiliary precursor shown in Table 1 below. Next, the thin film precursor compound and the auxiliary precursor were mixed in a molar ratio of 1:1, stored in a pressure vessel for 1 hour, and then H-NMR was measured.

By comparing the H-NMR spectrum results before and after mixing, additionally generated NMR peaks were judged to be impurities, and the integrated value of the generated NMR peaks was defined as the content of the impurities.

When the percentage value of the impurities content was less than 0.1%, it was evaluated as “no reaction”. When the percentage value of the impurities content exceeded 0.1%, it was evaluated as “reaction occurs”. The results are shown in Table 1 below.

As a specific example, the specific evaluation method for 1-iodobutane, which was evaluated as “no reaction” in Table 1 below, is as follows.

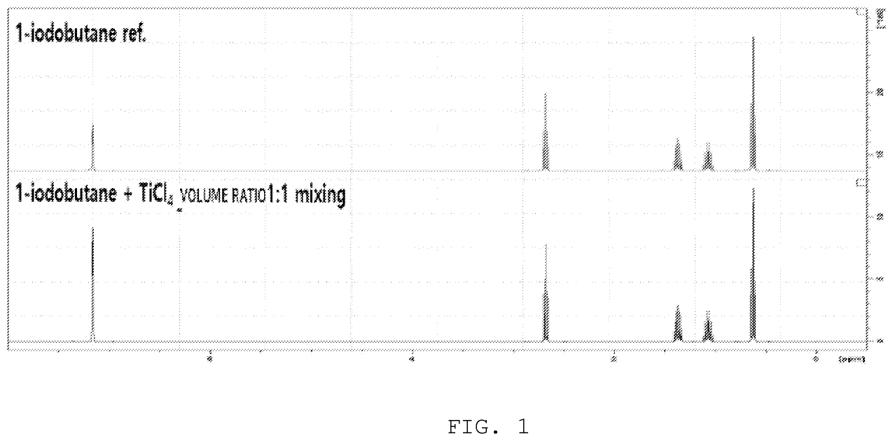

As shown in FIG. 1 below, compared to H-NMR measured for 1-iodobutane alone (corresponding to the upper drawing in FIG. 1), in H-NMR (corresponding to the lower drawing in FIG. 1) measured after mixing 1-iodobutane and TiCl₄ at a molar ratio of 1:1 and placing the mixture in a pressure vessel for 1 hour, newly created peaks were regarded as impurities, and the content of the impurities was calculated. The result was less than a reference value of 0.1%. Thus, the case was evaluated as “no reaction”.

The same evaluation process was performed for the remaining substances, and “Reaction occurs” or “No reaction” were indicated according to the results.

TABLE 1

| Thin film | | | |
|---|---|---|---|
| precursor | | Reactivity | |
| compound | Auxiliary precursor | test | Experiment |
| TiCl₄ | Diiodomethane | No reaction | — |
| TiCl₄ | 1-Iodobutane | No reaction | Example 1, |
| | | | Comparative |
| | | | Examples 1, 3 |
| TiCl₄ | 2-Iodobutane | No reaction | Examples 2, 4, |
| | | | Comparative |
| | | | Example 2 |
| TiCl₄ | Cyclohexyl iodide | No reaction | Example 5 |
| TiCl₄ | 2-Iodo-2-methyl propane | No reaction | Example 3 |
| TiCl₄ | 1-Bromo-1-methyl | No reaction | — |
| | cyclohexane | | |
| TiCl₄ | 3-Iodo-2,4- | No reaction | Example 6 |
| | dimethylpentane | | |
| TiCl₄ | Aniline | Reaction | — |
| | | occurs | |
| TiCl₄ | N-Methylaniline | Reaction | — |
| | | occurs | |
| TiCl₄ | N,N-Dimethylaniline | Reaction | — |
| | | occurs | |
| TiCl₄ | Acetonitrile | Reaction | |
| | | occurs | |
| TiCl₄ | Diethylether | Reaction | |
| | | occurs | |
| TiCl₄ | Anisole | Reaction | |
| | | occurs | |
| TiCl₄ | Dimethylsulfide | Reaction | |
| | | occurs | |
| TiCl₄ | 3-Ethyl-2-pentene | No reaction | Comparative |
| | | | Example 4 |
| TiCl₄ | 1,2,3-Trichloropropane | No reaction | Comparative |
| | | | Example 5 |

As shown in Table 1, among the 16 combinations presented, seven combinations in which an auxiliary precursor having an electron acceptor terminal group was mixed with a thin film precursor compound showed reactivity of less than 0.1%, indicating that the seven combinations exhibited reaction stability.

### Examples 1 to 6

The compound as shown in Table 1 was prepared as the auxiliary precursor, and TiCl₄ was prepared as the thin film precursor compound. The prepared auxiliary precursor and thin film precursor compound were placed in a canister and supplied to a vaporizer heated to 150° C. at a flow rate of 0.05 g/min using a liquid mass flow controller (LMFC) at room temperature. The auxiliary precursor and thin film precursor compound vaporized in the vaporizer were fed into a deposition chamber loaded with a substrate for 1 second at a feeding amount ratio of 1:1, and then argon gas was supplied thereto at 5,000 sccm for 2 seconds to perform argon purging. At this time, the pressure in the reaction chamber was controlled to 2.5 Torr.

Next, after introducing ammonia as a reactive gas into the reaction chamber at 1,000 sccm for 3 seconds, argon purging was performed for 3 seconds. At this time, the substrate on which a metal thin film is to be formed was heated to the temperature shown in Table 2 below. This process was repeated 200 to 400 times to form a TiN thin film having a thickness of 10 nm as a self-limiting atomic layer.

### Comparative Examples 1 and 2

The compound as shown in Table 1 was prepared as the auxiliary precursor, and TiCl₄ was prepared as the thin film precursor compound. The prepared auxiliary precursor was placed in a canister and supplied to a vaporizer heated to 150° C. at a flow rate of 0.05 g/min using a liquid mass flow controller (LMFC) at room temperature. The auxiliary precursor vaporized in the vaporizer was fed into a deposition chamber loaded with a substrate for 1 second, and then argon gas was supplied thereto at 5,000 sccm for 2 seconds to perform argon purging. At this time, the pressure in the reaction chamber was controlled to 2.5 Torr.

Then, the prepared TiCl₄ was placed in a separate canister and supplied to a separate vaporizer heated to 150° C. at a flow rate of 0.05 g/min using a liquid mass flow controller (LMFC) at room temperature. The TiCl₄ vaporized in the vaporizer was fed into the deposition chamber for 1 second, and then argon gas was supplied thereto at 5,000 sccm for 2 seconds to perform argon purging. At this time, the pressure in the reaction chamber was controlled to 2.5 Torr.

Next, after introducing ammonia as a reactive gas into the reaction chamber at 1,000 sccm for 3 seconds, argon purging was performed for 3 seconds. At this time, the substrate on which a metal thin film is to be formed was heated to the temperature shown in Table 2 below. This process was repeated 200 to 400 times to form a TiN thin film having a thickness of 10 nm as a self-limiting atomic layer.

### Comparative Example 3

The compound as shown in Table 1 was prepared as the auxiliary precursor, and TiCl₄ was prepared as the thin film precursor compound.

The prepared TiCl₄ was placed in a separate canister and supplied to a separate vaporizer heated to 150° C. at a flow rate of 0.05 g/min using a liquid mass flow controller (LMFC) at room temperature. The TiCl₄ vaporized in the vaporizer was fed into a deposition chamber for 1 second, and then argon gas was supplied thereto at 5,000 sccm for 2 seconds to perform argon purging. At this time, the pressure in the reaction chamber was controlled to 2.5 Torr.

Then, the prepared auxiliary precursor was placed in a canister and supplied to a vaporizer heated to 150° C. at a flow rate of 0.05 g/min using a liquid mass flow controller (LMFC) at room temperature. The auxiliary precursor vaporized in the vaporizer was fed into a deposition chamber loaded with a substrate for 1 second, and then argon gas was supplied thereto at 5,000 sccm for 2 seconds to perform argon purging. At this time, the pressure in the reaction chamber was controlled to 2.5 Torr.

Next, after introducing ammonia as a reactive gas into the reaction chamber at 1,000 sccm for 3 seconds, argon purging was performed for 3 seconds. At this time, the substrate on which a metal thin film is to be formed was heated to the temperature shown in Table 2 below. This process was repeated 200 to 400 times to form a TiN thin film having a thickness of 10 nm as a self-limiting atomic layer.

### Comparative Example 4

The compound as shown in Table 1 was prepared as the auxiliary precursor, and TiCl₄ was prepared as the thin film precursor compound. The prepared auxiliary precursor was placed in a canister and supplied to a vaporizer heated to 150° C. at a flow rate of 0.05 g/min using a liquid mass flow controller (LMFC) at room temperature. The auxiliary precursor vaporized in the vaporizer was fed into a deposition chamber loaded with a substrate for 1 second, and then argon gas was supplied thereto at 5,000 sccm for 2 seconds to perform argon purging. At this time, the pressure in the reaction chamber was controlled to 2.5 Torr.

Then, the prepared TiCl₄ was placed in a separate canister and supplied to a separate vaporizer heated to 150° C. at a flow rate of 0.05 g/min using a liquid mass flow controller (LMFC) at room temperature. The TiCl₄ vaporized in the vaporizer was fed into the deposition chamber for 1 second, and then argon gas was supplied thereto at 5,000 sccm for 2 seconds to perform argon purging. At this time, the pressure in the reaction chamber was controlled to 2.5 Torr.

Next, after introducing ammonia as a reactive gas into the reaction chamber at 1,000 sccm for 3 seconds, argon purging was performed for 3 seconds. At this time, the substrate on which a metal thin film is to be formed was heated to the temperature shown in Table 2 below. This process was repeated 200 to 400 times to form a TiN thin film having a thickness of 10 nm as a self-limiting atomic layer.

### Comparative Example 5

A TiN thin film was formed in the same manner as in Example 1, except that the auxiliary precursor used in Example 1 was replaced with the compound listed in Table 1.

### Test Examples

1) Deposition Evaluation (Deposition Rate Per Cycle)

An ellipsometer capable of measuring the optical properties of a thin film including thickness and refractive index using the polarization characteristics of light was used to measure the thickness of the formed thin film. The thickness of the thin film deposited per cycle was calculated by dividing the measured thickness value by the number of cycles. Based on the calculated values, deposition rate was evaluated, and the results are shown in Table 2 below.

2) Evaluation of Thin Film Resistance (Resistivity)

The surface resistance of the formed thin film was measured using the four-point probe method, and the resistivity value thereof was calculated based on the thickness value of the thin film.

The degree of improvement in resistivity (μΩ·cm) was calculated according to Equation 1 below.

Degree of improvement in resistivity (%)=[(Resistivity when precursor composition is used−Resistivity when no auxiliary precursor is used)/Resistivity when no auxiliary precursor is used]×100 [Equation 1]

TABLE 2

| | | | Deposition | Resistivity | |
|---|---|---|---|---|---|
| | | | rate (Unit: | (Unit: | Degree of |
| | | Deposition | Å/cycle) | μΩ · cm) | resistivity |
| | Auxiliary | temperature | (*Control | (*Control | improvement |
| Classification | precursor | (° C.) | group) | group) | (%) |
| Example 1 | 1-Iodobutane | 400 | 0.39 | 358 | −30 |
| | | | (*0.34) | (*518) | |
| Example 2 | 2-Iodobutane | 440 | 0.42 | 165 | −50 |
| | | | (*0.33) | (*329) | |
| Example 3 | 2-Iodo-2-methyl propane | 440 | 0.41 | 160 | −51 |
| | | | (*0.33) | (*329) | |
| Example 4 | 2-Iodobutane | 440 | 0.37 | 245 | −26 |
| | | | (*0.33) | (*329) | |
| Example 5 | Cyclohexyl iodide | 440 | 0.36 | 162 | −51 |
| | | | (*0.33) | (*329) | |
| Example 6 | 3-Iodopentane | 440 | 0.32 | 285 | −13 |
| | | | (*0.33) | (*329) | |
| Comparative | 1-Iodobutane | 400 | 0.38 | 1224 | 236 |
| Example 1 | | | (*0.34) | (*518) | |
| Comparative | 2-Iodobutane | 440 | 0.42 | 320 | 0.02 |
| Example 2 | | | (*0.33) | (*329) | |
| Comparative | 1-Iodobutane | 440 | 0.43 | 364 | −0.01 |
| Example 3 | | | (*0.33) | (*329) | |
| Comparative | 3-Ethyl-2-pentene | 440 | 0.28 | 537 | 63 |
| Example 4 | | | (*0.33) | (*329) | |
| Comparative | 1,2,3-Trichloropropane | 400 | 0.32 | 841 | 62 |
| Example 5 | | | (*0.34) | (*518) | |

*Control group: A TiN thin film formed without using an auxiliary precursor

As shown in Table 2, the case (Examples 1 to 6) of using 1-iodobutane, 2-iodobutane, 2-iodo-2-methyl propane, 2-iodobutane, cyclohexyl iodide, or 3-iodo pentane as the auxiliary precursor of the present invention and the thin film precursor compound in combination exhibited a deposition rate equivalent or similar to that of the case (Comparative Examples 1, 2, and 4) of using the auxiliary precursor as a growth inhibitor prior to the thin film precursor compound, the case (Comparative Example 3) of using the auxiliary precursor as a growth activator after introducing the thin film precursor compound, or the case (Comparative Example 5) of replacing the auxiliary precursor with an auxiliary precursor that is reactive with the thin film precursor compound. In addition, in the case of Examples 1 to 6, resistivity was reduced to a range of 160 to 358 μΩ·cm. In particular, compared to a control group not using the auxiliary precursor, resistivity characteristics were greatly reduced to a range of −51% to −10%, indicating that thin film growth rate was appropriately controlled and electrical properties were improved.

Specifically, the case of Comparative Example 1 in which 1-iodobutane was used as an auxiliary precursor and the auxiliary precursor acted as a growth inhibitor exhibited a much higher resistivity (1,224 μΩ·cm) than that (518 μΩ·cm) of the control group not using the auxiliary precursor.

In addition, the case of Comparative Example 2 in which 2-iodobutane was used as an auxiliary precursor and the auxiliary precursor acted as a growth inhibitor exhibited a resistivity of 320 μΩ·cm that was not significantly different from the resistivity value (329 μΩ·cm) of the control group not using the auxiliary precursor. The case of Comparative Example 3 using 2-iodobutane as a growth activator exhibited a resistivity of 364 μΩ·cm that was not significantly different from the resistivity value (329 μΩ·cm) of the control group not using the auxiliary precursor. These results indicated that, in Comparative Examples 2 and 3, there was no effect of improving the electrical properties of a thin film.

In addition, although it was confirmed that the auxiliary precursor did not react with the thin film precursor compound at room temperature, Comparative Example 4 using an auxiliary precursor that does not contain the electron acceptor terminal group of the present invention as a growth inhibitor did not show an effect of improving the electrical properties of a thin film.

In addition, Comparative Example 5 using a thin film precursor compound and an auxiliary precursor that reacts with the thin film precursor compound did not show an effect of improving the electrical properties of a thin film.

3) Impurities Reduction Characteristics

To compare the characteristics of reducing impurities (i.e., process by-products) in the formed thin film having a thickness of 10 nm, X-ray photoelectron spectroscopy (XPS) was performed on titanium(Ti), nitrogen (N), chlorine (Cl), carbon (C), and oxygen (O), and the results are shown in Table 3 below.

TABLE 3

| | Auxiliary | Impurities (%) | | | | |
|---|---|---|---|---|---|---|
| Classification | precursor | Ti | N | Cl | C | O |
| Ref | None | 38.07 | 38.01 | 0.10 | 0.11 | 23.71 |
| Comparative | 1,2,3- | 37.21 | 33.18 | 1.02 | 0.51 | 28.08 |
| Example 5 | Trichloropropane | | | | | |
| Example 6 | 3-Iodopentane | 39.18 | 39.18 | 0.05 | 0.01 | 21.63 |

As shown in Table 3, in the case (Example 6) of using the auxiliary precursor according to the present invention and the thin film precursor compound at the same time, compared to the case (Comparative Example 5) in which a thin film precursor compound and an auxiliary precursor that is inappropriate in terms of reactivity with the thin film precursor compound were injected at the same time, the intensities of Cl and C decreased to 0.01%, indicating that impurities reduction characteristics were excellent. In particular, in the case of Comparative Example 5, since the auxiliary precursor that reacts with the thin film precursor compound was added in the thin film deposition process, no carbon should have been detected in theory. However, carbon, presumed to originate from trace amounts of CO and/or CO₂ contained in the thin film precursor compound, purge gas, and reaction gas, was detected. In Example 5 of the present invention, the carbon intensity decreased compared to Comparative Example 5 even though an auxiliary precursor, which is a hydrocarbon compound, was added during thin film deposition. These results indicate that the auxiliary precursor of the present invention has excellent impurities reduction characteristics.

In particular, in Comparative Example 5, a compound having a structure similar to the auxiliary precursor of the present invention and the precursor composition were added at the same time as in the present invention. However, the intensity of impurities of Comparative Example 5 was much higher than that of Example 6 or the control group, indicating that Comparative Example 5 had no effect of improving film quality.

1. An auxiliary precursor, wherein the auxiliary precursor is a straight-chain, branched, cyclic, or aromatic compound represented by Chemical Formula 1 below, and is mixed with a thin film precursor compound and used.
AnBmXoYiZj, [Chemical Formula 1]
wherein A is carbon or silicon; B is hydrogen, an alkyl having 1 to 10 carbon atoms, a cycloalkyl having 3 to 10 carbon atoms, or an alkoxy having 1 to 10 carbon atoms; X comprises one or more of fluorine (F), chlorine (Cl), bromine (Br), and iodine (I); Y and Z independently comprise one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.

2. The auxiliary precursor according to claim 1, wherein, when the auxiliary precursor and the thin film precursor compound are mixed at a molar ratio of 1:1, pressurized, and then an ¹H-NMR spectrum thereof is measured, the auxiliary precursor is a compound in which an integrated value of newly generated peaks is less than 0.1% based on an ¹H-NMR spectrum for the auxiliary precursor.

3. A thin film precursor composition, comprising an auxiliary precursor and a thin film precursor compound, wherein the auxiliary precursor is a straight-chain, branched, cyclic, or aromatic compound represented by Chemical Formula 1 below and the thin film precursor compound is represented by Chemical Formula 2 below.
AnBmXoYiZj, [Chemical Formula 1]
wherein A is carbon or silicon; B is hydrogen, an alkyl having 1 to 10 carbon atoms, a cycloalkyl having 3 to 10 carbon atoms, or an alkoxy having 1 to 10 carbon atoms; X comprises one or more of fluorine (F), chlorine (Cl), bromine (Br), and iodine (I); Y and Z independently comprise one or more selected from the group consisting of oxygen, nitrogen, sulfur, and fluorine and are different from each other; n is an integer from 1 to 15; o is an integer greater than or equal to 1; m is 0 to 2n+1; and i and j are integers from 0 to 3.
MₓL_{y}, [Chemical Formula 2]
wherein x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; y is an integer from 0 to 6; and L is H, C, N, O, F, P, S, Cl, Br, or I or a ligand consisting of a combination of two or more selected from the group consisting of H, C, N, O, F, P, S, Cl, and Br.

4. The thin film precursor composition according to claim 1, wherein the auxiliary precursor and the thin film precursor compound have a weight ratio of 1:99 to 99:1.

5. The thin film precursor composition according to claim 3, wherein the auxiliary precursor comprises one or more selected from compounds represented by Chemical Formulas 3 to 14 below. 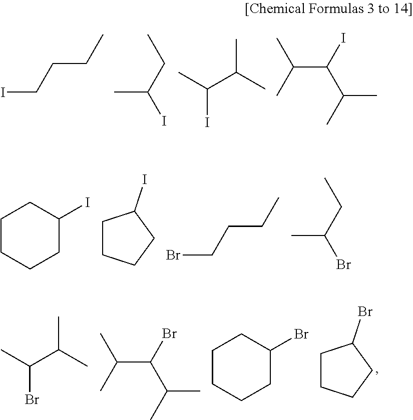
wherein a line is a bond, carbon is located at a point where bonds meet without indicating a separate element, and the number of hydrogen atoms satisfying a valence of the carbon is omitted.

6. The thin film precursor composition according to claim 3, wherein the thin film precursor composition is used in an atomic layer deposition (ALD) process, a plasma atomic layer deposition (PEALD) process, a chemical vapor deposition (CVD) process, or a plasma chemical vapor deposition (PECVD) process.

7. A method of forming a thin film, comprising injecting the thin film precursor composition according to claim 3 into a chamber and adsorbing the thin film precursor composition on a surface of a loaded substrate.

8. The method according to claim 7, comprising:
i) vaporizing the thin film precursor composition and adsorbing the thin film precursor composition onto a surface of a substrate loaded in a chamber;
ii) performing first purging of an inside of the chamber using a purge gas;
iii) supplying a reaction gas into the chamber; and
iv) performing second purging of the inside of the chamber using a purge gas.

9. The method according to claim 7, wherein the thin film precursor composition is transferred into an ALD chamber, a CVD chamber, a PEALD chamber, or a PECVD chamber by a VFC method, a DLI method, or an LDS method.

10. The method according to claim 7, wherein an auxiliary precursor and a thin film precursor compound constituting the thin film precursor composition are fed into the chamber at a feeding ratio (mg/cycle) of 1:0.1 to 1:20.

11. The method according to claim 7, wherein the reaction gas is a reducing agent, a nitrifying agent, or an oxidizing agent.

12. (canceled)

13. The method according to claim 7, wherein the thin film is an oxide film, a nitride film, or a metal film.

14. The method according to claim 13, wherein the thin film comprises a multilayer structure consisting of two or three layers.

15. A semiconductor substrate fabricated using the method according to claim 7.
